(19) United States
(12) Patent Application Publication
(10) Pub. No.: US 2008/0247046 A1
(43) Pub. Date: Oct. 9, 2008

(54) Glare free mirror pane as well as a rear view mirror with such a mirror pane

(76) Inventors: Jurgen Singer, Rosstal (DE); Werner Lang, Ergersheim (DE); Wolfgang Fukarek, Fischbach (DE)

Correspondence Address: MCNAIR LAW FIRM, P.A., P.O. BOX 10827, GREENVILLE, SC, 29603-0827, US

(21) Appl. No.: 11/974,984

(22) Filed: Oct. 17, 2007

(30) Foreign Application Priority Data
Oct. 17, 2006 (DE) 202006015876.6

(51) Int. Cl. B60R 1/08; G02B 1/10; C23C 14/08; C23C 14/14

(52) U.S. Cl. 359/603; 204/192.1

(57) ABSTRACT

Proposed is a glare free pan for a rear view service in motor vehicles, possessing a curved transparent substrate, the front surface of which forms the exposed surface of the said mirror. Upon the rear surface of said substrate is applied, in appropriate thicknesses, by sputtering at least four successive and contiguous layers of respectively niobium pentoxide, silicon dioxide, chromium and a protect covering of lacquer. The chromium layer provides the effective reflecting quality of the said mirror. The composition and thicknesses of the layers allows the mirror to reflectively function in visible light wavelengths suitable for both night and day service. Proposed also is a method for the manufacture of the above as well as its assembly into a rear view mirror ready for vehicle installation.

### BACKGROUND OF THE INVENTION

The invention concerns a glare free mirror pane and a method for the manufacturing the same, as well as a glare free rear view mirror for motor vehicles.

Reflectant coatings of silver on conventional mirror panes, in spite of sealing, are frequently subject to corrosion, which is detrimental to viewing in the field of sight and, eventually, can lead to a complete loss of functionality of a mirror so affected. Further, a reduction of the disturbing effect of glare would be of advantage in both day and night rear view service. Consequently, efforts have been made to provide glare prevention over the entire wavelength range of visible light. In the bright ambience of daylight the human eye possesses a maximum spectral sensitivity at 555 nm, which wave length encompasses yellowish-green colorations. Conversely, in dark surroundings, for instance at night, when light is largely excluded, the maximum spectral sensitivity tends to migrate into the blue range of the spectrum. On this account, a mirror, with a high degree of reflectivity in the blue spectral range is considered to be particularly adaptable for both day and night service. It is also true, that from none other than aesthetic grounds, mirrors often are designed to reflect in the said blue range.

A mirror of this kind has been made known by EP-B-1099671. This disclosed front surface mirror employs chromium as the reflecting coating and consequentially is very resistant to corrosion. Disturbing dazzling effects are minimized by means of additional coatings, namely Al₂O₃, ZrO₂, SnO₂, and TiO₂. The reflection factor of mirrors incorporating such coatings is found to be greater in the short-wave spectrum (blue) of visible light than in the long wave spectrum (red) of visible light. For this reason, such mirrors provide a bluish reflection. Difficulties with these blue-oriented mirrors lie in providing a satisfactory homogeneity of reflectance over the entire surface of the mirror.

In order to achieve a reduction of a glare effect, it is customary to block an overly blue toned portion of the spectrum, which, as said above, is that range of the visible spectrum most adaptable to night service. If this is done, then the reflecting factor of a mirror of this design is less in the blue spectrum than in the long-wave red spectrum. Unfortunately, mirrors are purposely designed to tend toward a red reflection. Disadvantageously, however, even in highly rated mirror classifications, such a mirror exhibits its maximum intensity of reflected light in the red, i.e., long wave spectrum. Essentially, this results in an excessive quantity of light, which, in turn, promotes excess glare in daytime reflectance.

Thus it is the purpose of the present invention to create a mirror pane of reduced glare and thereby a glare free rearview mirror for motor vehicles, wherein a reasonable compromise between glare activity in night and day operation can be found.

### SUMMARY OF THE INVENTION

The objectives of the invention are accomplished by means of the combination of a coating of niobium pentoxide (Nb₂O₅), applied onto a transparent substrate, a color rendering layer of silicon nitride (Si₃N₄) laid thereon and finally a chromium layer to serve as a reflecting surface, it is possible to create a glare diminishing effect of a sufficient degree to be employed in both day and night services. A further attribute of this combination is that the said blue tinge is very well homogenized over the entire pane surface.

The mirror pane possesses over the entire spectral range of visible light a somewhat reduced reflection factor, for instance, at 700 nm wave length, the reflectance runs some 32%, at 400 nm wave length the reflectance is 65%. The sought after blue tinge exhibits an unchangeable rendition of color, Thereby, for the first time, it becomes possible to fashion a reflecting surface effective in the blue tinge range by using niobium pentoxide and silicon nitride. This here described surface, because of its basic chrome deposit, can offer an excellent resistance to corrosion.

The realization of the invention, giving consideration to the compromises made between a reduced glare effect in both night and day services is very advantageous.

By means of the advantageous construction of the invention the desired degree of reflectance and the desired blue tinting is satisfactorily achieved.

By means of slight curvature the described glare free mirror adapts itself very well as a rear view mirror for motor vehicles.

Glass is especially preferred as the substrate or the carrier of the individually mentioned coatings of the mirror since glass possesses outstanding optical characteristics as well as an excellent mechanical strength. It is, however, entirely possible to employ a transparent plastic as a substrate for the same purpose.

The method in accord with the invention presents an advantageous possibility for the manufacture of the invented mirror pane.

### DESCRIPTION OF THE DRAWINGS

The invention will be more readily understood from a reading of the following specification and by reference to the accompanying drawings forming a part thereof, wherein an example of the invention is shown and wherein:

FIG. 1 a schematic sectional drawing of the stratification of the layers in accord with the present invention, and

FIG. 2 a graphic presentation of the range of reflectivity of a mirror pane in accord with the present invention and shown as a function of the wavelength.

### DESCRIPTION OF A PREFERRED EMBODIMENT

Referring now in more detail to the drawings, the invention will now be described in more detail.

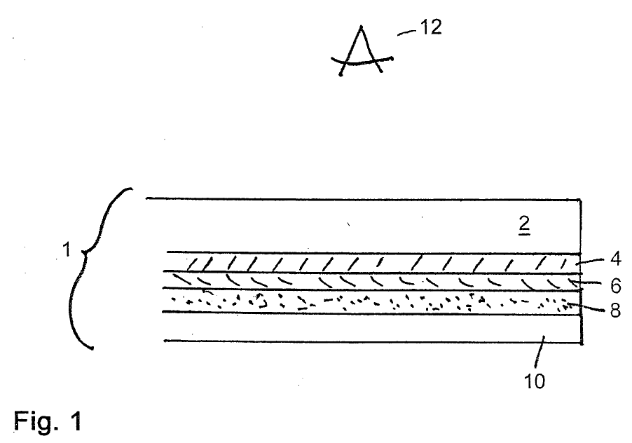

FIG. 1 shows the stratification of layers of an exemplary embodiment of a mirror pane 1 of the present invention. Upon a substrate or carrier 2, which is composed of glass, the first layer of niobium pentoxide (Nb₂O₅) 4 is deposited. Superimposed upon this first layer of niobium pentoxide 4 is a second layer of silicon nitride 6 upon which a third layer 8 is deposited, this being of chromium and serving as the actual reflecting surface. Finally, the said chromium layer is protected from mechanical damage by a lacquer coating 10. The lacquer coating 10 is not required for maintaining a stability against corrosion. The reference number 12 represents the direction of view from which an observer would look into the mirror 1.

The niobium pentoxide layer 4 has a thickness of 38 nm±10 nm, the silicon layer 6 is 49 nm thick, ±20 nm and the reflecting layer 8, this being of chromium, has a thickness of 50 nm with a variance of ±10 nm. The thicknesses of the individual layers 4, 6 and 8 are so selected that the desired reflectant degree exceeds 40% mm—this being a condition suitable for installation as motor vehicle rear vision mirrors—and the mirror a whole can assure service day and night with a sufficient freedom from glare.

The deposition of the layers 4, 6 and 8 is carried out by sputtering. For this operation, inline sputtering devices of the firm Leybold Optics are used. With these said devices, substrate 2 and the individual targets for the various for the different layers are stratified vertically, next to one another. The different targets are stationarily located continguently to one another, while the substrate is moved linearly along the said targets. For the niobium pentoxide layer 4, a target of niobium pentoxide is made and for the reflecting layer 8 of chromium a target of that metal is used. The silicon reacts in an atmosphere containing nitrogen in accord with the reaction formula:

3Si+2N₂→Si₃N₄

thus forming in transit silicon nitride, which then precipitates itself on the niobium pentoxide layer 4.

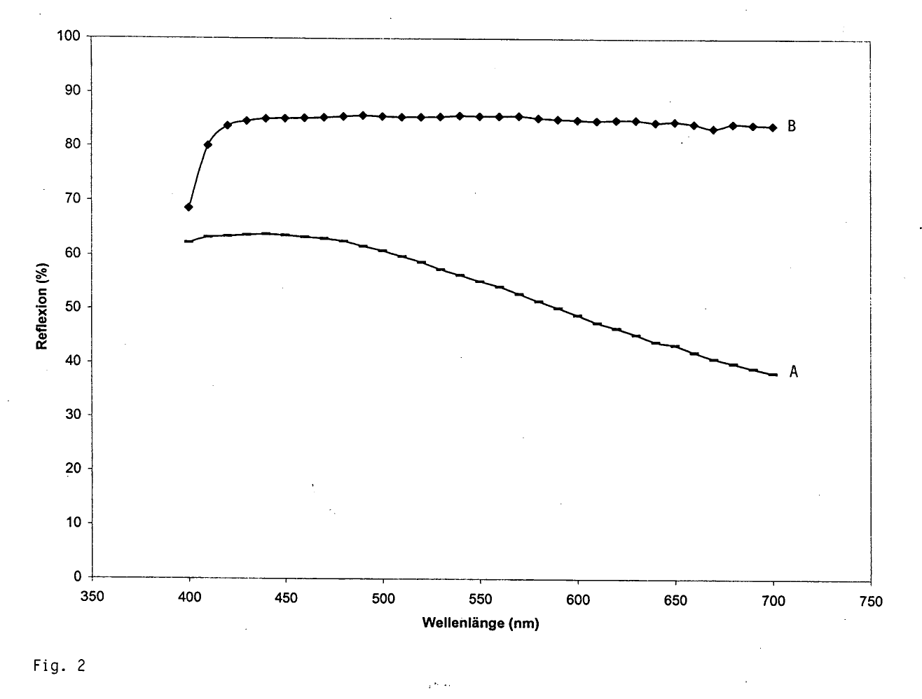

FIG. 2 shows a graphic presentation of the degree of reflection factor of a mirror pane in accord with FIG. 1, characterized as a function of the wavelength. The curve A shows the reflection factor (in percent) of the mirror expressed as a function of the wave length (in nm) of the incident light on the mirror surface. This spectral reflection factor varies within a range of 400 nm and 700 nm which in turn represents a variance between a maximum of 68% and a minimum of 48%. The curve B designates the spectral reflection of a standard reflector.

While a preferred embodiment of the invention has been described using specific terms, such description is for illustrative purposes only, and it is to be understood that changes and variations may be made without departing from the spirit or scope of the following claims.

What is claimed is:

1. A glare free mirror pane, especially for rear vision service in motor vehicles comprising:
a transparent substrate having a front side which forms a front surface of a mirror pane;
a first layer of niobium pentoxide applied to a rear side of said substrate;
a second layer including silicon nitride deposited on the first layer of niobium pentoxide; and
a third layer of chromium being the reflecting surface of said mirror pane deposited on said second layer;

2. The device of claim 1 wherein said first, second and/or the third layer is a sputtered surface.

3. The device of claim 1 wherein thicknesses of the first and second layers are so selected so that the reflection factor of the mirror pane is greater in the range of the short waved zone of the visible light spectrum than in the range of the long waved zone of the visible light spectrum.

4. A glare free mirror pane in accord with claim 1 wherein thicknesses of the first, second and third layers are selected so that an integrated reflection factor lies in a range between 43% and 53%, preferably between 48% and 52% and most advantageously between 49% and 51%.

5. A glare free mirror pane in accord claim 1 wherein the thickness of the first layer, namely of niobium pentoxide is 38 nm±10 nm.

6. A glare free mirror pane in accord with claim 1 wherein the thickness of the second layer, namely of silicon nitride, is 49 nm±20 nm.

7. A glare free mirror pane in accord with claim 1 wherein characterized, in that the thickness of the third layer, namely of chromium, is 50 nm±10 nm.

8. A glare free mirror pane in accord with claim 1 wherein the substrate is slightly curved.

9. A glare free mirror pane in accord with claim 1 wherein the substrate consists of glass.

10. A glare free mirror pane in accord with claim 1 wherein the mirror pane is chromium, and including a fourth layer of protective lacquer is applied to the pane.

11. A method for the manufacture of a mirror pane comprising of the following steps.
Placing a substrate in an in-line sputtering device,
sputtering a first layer of niobium pentoxide onto the rear side of the substrate from a niobium pentoxide target,
sputtering a second layer of silicon nitride onto the first layer (4) from a target of silicon in the ambience of nitrogen, and
sputtering a third, mirror deposition layer of chromium onto the second layer from a target of chromium.

12. The method of claim 11, including applying a fourth layer, including a protective lacquer onto the chromium layer.

13. The method of claim 11 wherein the substrate is applied by being ion-receptively transported in relation to the stationary target which has a fixed position.

14. A glare free rear view mirror with a mirror pane made in accordance with claim 11.
